(19) United States
(12) Patent Application Publication
(10) Pub. No.: US 2025/0006704 A1
(43) Pub. Date: Jan. 2, 2025

(54) SEMICONDUCTOR DEVICE WITH A SPACED SUPPLY VOLTAGE AND GROUND REFERENCE

(71) Applicant: Micron Technology, Inc., Boise, ID (US)

(72) Inventors: Wei Zhou, Boise, ID (US); Kunal R. Parekh, Boise, ID (US)

(21) Appl. No.: 18/736,318

(22) Filed: Jun. 6, 2024

Related U.S. Application Data
(60) Provisional application No. 63/524,555, filed on Jun. 30, 2023.

(51) Int. Cl. H01L 25/065; H01L 23/00; H01L 25/00; H01L 25/18; H10B 80/00

(52) U.S. Cl. CPC H01L 25/0657; H01L 24/08; H01L 24/80; H01L 25/18; H01L 25/50; H10B 80/00; H01L 2224/08146; H01L 2224/80895; H01L 2224/80896; H01L 2225/06544; H01L 2225/06548; H01L 2225/06586; H01L 2924/1431; H01L 2924/1434

(57) ABSTRACT

A semiconductor device with a spaced supply voltage and ground reference is disclosed. A stack of semiconductor dies includes a first semiconductor die, one or more second semiconductor dies, and first and second contacts. A gap fill is disposed over a distal end of the one or more second semiconductor dies opposite the first semiconductor die. A first rail (e.g., supply voltage) is disposed at a distal end of the gap fill opposite the first semiconductor die, and a first via extends from the first rail to the first contact. A layer of dielectric material is disposed at least partially over the first rail. A second rail (e.g., ground reference) is disposed at the layer of dielectric material, and a second via extends from the second rail to the second contact. Third and fourth exposed contacts are coupled to the first and second rails, respectively.

### CROSS-REFERENCE TO RELATED APPLICATION(S)

The present application claims priority to U.S. Provisional Patent Application No. 63/524,555, filed Jun. 30, 2023, the disclosure of which is incorporated herein by reference in its entirety.

### TECHNICAL FIELD

The present disclosure generally relates to semiconductor device assemblies and more particularly relates to a semiconductor device with a spaced supply voltage and ground reference.

### BACKGROUND

Microelectronic devices generally have a die (e.g., a chip) that includes integrated circuitry with a high density of very small components. Typically, dies include an array of bond pads electrically coupled to the integrated circuitry. The bond pads are external electrical contacts through which the supply voltage, signals, etc., are transmitted to and from the integrated circuitry. After dies are formed, they are “packaged” to couple the bond pads to a larger array of electrical terminals that can be more easily coupled to the various power supply lines, signal lines, and ground lines. Conventional processes for packaging dies include electrically coupling the bond pads on the dies to an array of leads, ball pads, or other types of electrical terminals and encapsulating the dies to protect them from environmental factors (e.g., moisture, particulates, static electricity, and physical impact).

### BRIEF DESCRIPTION OF THE DRAWINGS

FIG. 1 illustrates a simplified schematic cross-sectional view of a semiconductor device assembly in accordance with an embodiment of the present technology.

FIG. 2 illustrates a simplified schematic partial plan view of a semiconductor device assembly in accordance with an embodiment of the present technology.

FIGS. 3-7 illustrate simplified schematic cross-sectional views of a series of steps for fabricating semiconductor device assemblies in accordance with embodiments of the present technology.

FIG. 8 illustrates a schematic view of a system that includes a semiconductor device assembly configured in accordance with an embodiment of the present technology.

FIG. 9 illustrates a method of fabricating a semiconductor device assembly in accordance with an embodiment of the present technology.

### DETAILED DESCRIPTION

Multiple semiconductor dies can be packaged into a single semiconductor device that can operate cooperatively and provide a particular functionality; however, these designs can also introduce various challenges. For example, semiconductor devices can be at risk of overheating due to an increased amount of heat generated by multiple dies within a single package. These dense package structures can require complex routing that dictates the positioning of semiconductor dies within the package. For example, semiconductor dies that include dense circuitry or require large amounts of external connections (e.g., power, ground, input/output (I/O)) to operate are positioned within the package at locations that prioritize connectivity over thermal advantages. Often, however, these same semiconductor dies (e.g., logic dies) produce the largest amount of heat due to the density of circuitry within these dies or the large power distributions required to operate these dies. Thus, semiconductor devices can benefit from alternate thermal regulation techniques, particularly those that prioritize thermal dissipation from semiconductor devices that produce a great amount of heat (e.g., logic dies).

Take for example, a memory device that includes a logic die (e.g., a memory controller or interface die) and one or more memory dies within a single package. In one design, the memory dies can be stacked onto the logic die such that the logic die is placed at the bottom of the package. In these designs, the semiconductor die producing the greatest amount of heat, the logic die, is located farthest from an upper surface of the package through which heat can be dissipated most efficiently (e.g., due to thermal components, such as heat sinks and heat spreaders, disposed at thereat). As a result, this design may suffer from poor thermal regulation, which can damage and decrease the efficiency of the device.

In contrast to this design, when high heat-producing dies are implemented at the top of a package (e.g., the logic die is implemented above the one or more memory dies), heat can more easily dissipate from the logic die through the upper surface of the package. In this arrangement, however, it can be difficult to implement the number of external connections necessary to provide adequate connectivity to the logic die. For example, external connectivity can be provided by implementing pass-through vias through the memory dies on which the logic die is stacked. When large amounts of pass-through vias are implemented through the memory dies, these pass-through vias can utilize a large portion of the circuit area on the memory dies. In doing so, the space available for circuitry implemented on the memory dies can be limited, which can increase routing complexity or reduce memory capacity, efficiency, or reliability. Moreover, there may be little flexibility in the locations at which these pass-through vias are implemented. Thus, when signals carried by the pass-through vias are needed far from these vias, large amounts of circuitry may be needed to carry signals to their appropriate location, increasing circuit density and device cost.

To address these problems and others, the present technology relates to a semiconductor device with a spaced supply voltage and ground reference. The semiconductor device can include a stack of semiconductor dies having a first semiconductor die, one or more second semiconductor dies, and first and second contacts coupled with circuitry at the stack of semiconductor dies. A gap fill can be disposed at least partially around the stack of semiconductor dies and over a distal end of the one or more second semiconductor dies opposite the first semiconductor die to mechanically support the semiconductor device. One or more first rails (e.g., supply voltage rails or ground reference rails) are disposed at a distal end of the gap fill opposite the first semiconductor die, and a first via extends from the first rail to the first contact. In this way, the first via can carry signals (e.g., supply voltage signals or ground signals) from the first rails to the first contact. In some cases, additional vias can extend from the first rails to the stack of semiconductor dies to provide additional connections to the signals carried by the first rails. A layer of dielectric material is disposed at least partially over the first rail. One or more second rails (e.g., supply voltage rails or ground reference rails) are disposed at the layer of dielectric material, and a second via extends from the second rail to the second contact. In doing so, signals carried by the second rails can be communicated to the stack of semiconductor dies. Third and fourth contacts are coupled to the first and second rails, respectively. The third and fourth contacts can be exposed at a periphery of the semiconductor device such that the contacts can be coupled with external components to enable signals to be communicated between the external components and the stack of semiconductor dies.

In some embodiments, one or more fifth contacts can be exposed at the periphery of the semiconductor device. Third vias extend from the one or more fifth contacts through the gap fill and the layer of dielectric material and couple with the stack of semiconductor dies. The third vias can be laterally spaced from the first rails and the second rails such that third vias are electrically isolated from the first rails and the second rails. In some cases, the fifth contacts and the third vias can be used to communicate input signaling and output signaling to/from the semiconductor device.

The present technology provides many advantages, some of which are discussed herein. Firstly, the first rails and the second rails can be vertically spaced from one another. In this way, the routing of the first rails and the second rails can be routed in additional arrangements that were previously forbidden due to overlap when implementing these rails at the same level. As a result, vias can be extended to the stack of semiconductor dies at a greater number of locations, thereby increasing design flexibility of the semiconductor device and enabling additional routing schemes to be implemented. In yet other aspects, the locations at which vias can be implemented are not limited to areas within the footprint of the second semiconductor dies stacked on the first semiconductor die. Instead, vias can be disposed through the gap fill at any location, including at a portion of the first semiconductor die exposed beyond the second semiconductor dies. The additional design flexibility provided by the ability to implement vias within the gap fill can enable additional routing schemes to be implemented. As another advantage, the present technology allows for high heat-producing dies (e.g., logic dies) to be implemented at the top of the package while providing adequate connectivity to these dies. In doing so, the semiconductor device can have improved thermal properties.

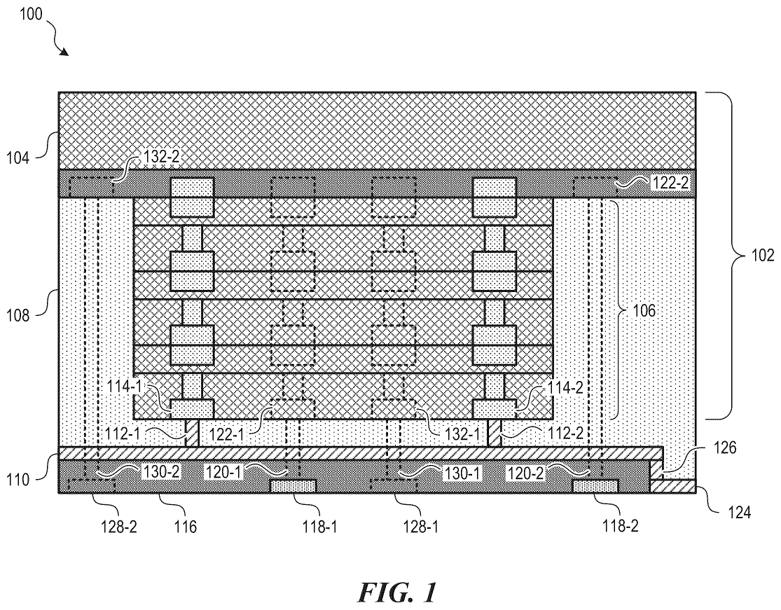

FIG. 1 illustrates a semiconductor device assembly 100 that includes a stack of semiconductor dies 102, including a semiconductor die 104 (e.g., a logic die) and one or more semiconductor dies 106 (e.g., memory dies), coupled (e.g., electrically and mechanically) with one another and the semiconductor die 104. The semiconductor dies 106 can couple with one another or the semiconductor die 104 through any appropriate technique, for example, hybrid bonding. In some implementations, the semiconductor device assembly 100 is a memory device. In this way, the semiconductor die 104 can implement an interface die or a memory controller, and the semiconductor dies 106 can comprise memory dies. In some embodiments, the semiconductor die 104 may require adequate connectivity to receive power, ground, I/O, or other signaling from external components with which the semiconductor device assembly 100 is coupled.

Metallization layers having circuitry, such as transistors, diodes, traces, lines, vias, and other circuit elements, can be disposed at the front sides of the semiconductor dies 106 and the semiconductor die 104. The semiconductor dies 106 can be coupled with the semiconductor die 104 such that front sides of the semiconductor dies 106 face toward the semiconductor die 104. In other cases, the back sides of the semiconductor dies 106, opposite the front sides, can face toward the semiconductor die 104. The semiconductor die 104 can face toward the semiconductor dies 106 such that a front side of the semiconductor die 104 faces a front side of the semiconductor dies 106. In other embodiments, the semiconductor die 104 can face away from the semiconductor dies 106 such that a back side of the semiconductor die opposite the front side faces toward the semiconductor dies 106. The stack of semiconductor dies 102 can be coupled through any appropriate circuitry. For example, interconnects between the stack of semiconductor dies 102 can be implemented using any number of traces, lines, vias, contact pads, through-silicon vias (TSVs), or any other connective circuitry.

The semiconductor die 104 can have a footprint that is larger than a footprint of the semiconductor dies 106. Thus, a portion of the semiconductor die 104 can be exposed beyond the footprint of the semiconductor dies 106. A gap fill 108, such as a dielectric fill (e.g., silicon oxide, silicon nitride, silicon carbide, or silicon carbon nitride), oxide fill (e.g., silicon oxide), or mold resin, is disposed at least partially around the stack of semiconductor dies 102. For example, the gap fill 108 can be disposed at the semiconductor die 104, around the semiconductor dies 106, and over a distal end of the semiconductor dies 106 opposite the semiconductor die 104.

One or more rails 110 can be disposed at a distal end of the gap fill opposite the semiconductor die 104. The one or more rails 110 can include conductive material capable of communicating signaling. The rails 110 can be configured to carry a specific signal to the stack of semiconductor dies 102. For example, the rails 110 can be configured to communicate source voltage signals or act as a ground reference by connecting (e.g., through connective circuitry, such as traces, lines, vias, or contact pads) to a contact arranged in a location that is intended to attach to an external component capable of providing such signals and a contact configured to receive such signals. One or more vias 112 (e.g., via 112-1 and via 112-2) can extend from the rails 110 through the gap fill 108 to contacts 114 (e.g., contact 114-1 and contact 114-2) coupled with circuitry at the stack of semiconductor dies 102. Any number of vias 112 can extend from the rails 110. For example, a plurality of vias 112 can extend from a single one of the rails 110 and can be spaced across a major axis of the rails 110 along which the rails 110 extend. As illustrated, the via 112-1 and the via 112-2 extend from a same one of the rails 110 at different lateral locations.

As illustrated, the vias 112 couple with contacts 114 exposed at the distal end of the semiconductor dies 106 opposite the semiconductor die 104. In some cases, the contacts 114 can connect, through vias that extend from the contacts 114 through the semiconductor dies 106 (e.g., without connecting to circuitry at metallization layers on these dies), to circuitry (e.g., contact pads, traces, lines, vias, transistors, diodes, or other circuit elements) at the semiconductor die 104. In other cases, the contacts 114 can connect to circuitry at the semiconductor die 104 through metallization layers at the semiconductor dies 106 and interconnects coupling the stack of semiconductor dies 102 with one another. In yet other aspects, the contacts 114 do not connect with circuitry at the semiconductor die 104 but instead connect to circuitry at one or more of the semiconductor dies 106. Thus, the vias 112 can connect with any subset of semiconductor dies within the stack of semiconductor dies 102 directly or by routing through metallization layers within any subset of semiconductor dies of the stack of semiconductor dies 102.

Although the vias 112 are illustrated as extending to the semiconductor dies 106 from within the footprint of these dies, the vias 112 can alternatively or additionally extend from a portion of the rails 110 beyond the footprint of the second semiconductor dies 106. The vias 112 can extend through the gap fill 108 beyond the footprint of the semiconductor dies 106 to contacts at an exposed portion of the semiconductor die 104. Thus, the vias 112 can extend between the rails 110 and the semiconductor die 104 without extending through the semiconductor dies 106.

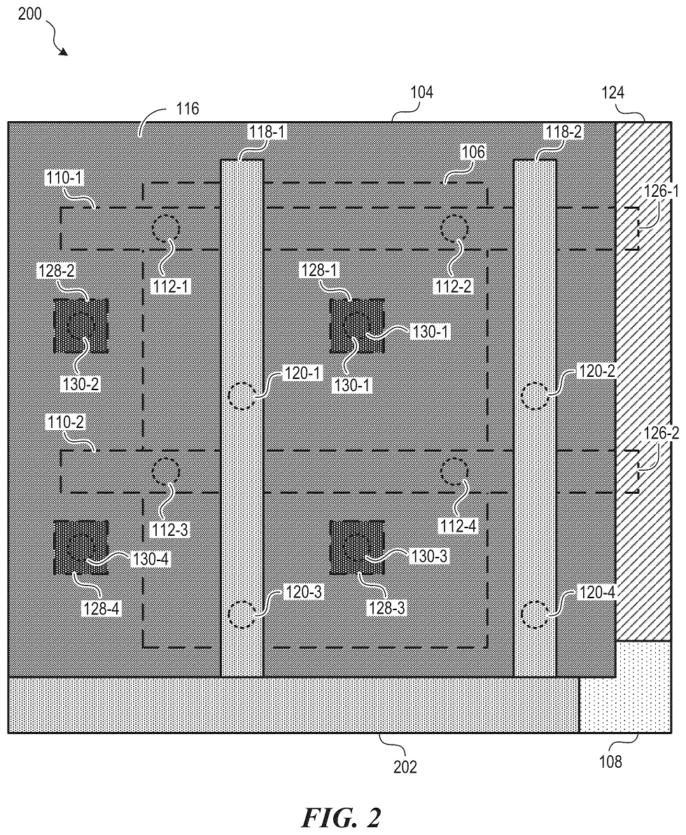

A layer of dielectric material 116 (e.g., silicon oxide, silicon nitride, silicon carbide, silicon carbon nitride, or any other dielectric material) can be disposed at the distal end of the gap fill 108 opposite the semiconductor die 104. The layer of dielectric material 116 can be disposed at least partially over the rails 110 to insulate the rails 110 from other circuitry at the layer of dielectric material 116. For example, one or more rails 118 can be disposed at the layer of dielectric material 116 and spaced vertically (e.g., along an axis normal to the plane along which the rails 118 or the rails 110 extend) from the rails 110. In this way, the rails 110 and the rails 118 can be vertically separated by at least a portion of the layer of dielectric material 116. The rails 118 can be exposed at a periphery of the semiconductor device assembly 100 (e.g., at a distal end of the semiconductor device assembly 100 opposite the semiconductor die 104). In other cases, the rails 118 can be at least partially embedded within the layer of dielectric material 116, and a contact (e.g., an example of which is illustrated in FIG. 2) coupled with the rails 118 can be exposed at the periphery of the semiconductor device assembly 100 to enable external components to electrically couple with the rails 118.

The rails 118 (rail 118-1 and rail 118-2) can be implemented similar to the rails 110. For example, the rails 118 can include conductive material capable of communicating signaling. In aspects, the rails 118 and the rails 110 can be used to carry different kinds of signals. For example, the rails 110 can be used to carry source voltage signals and the rails 118 can carry ground signaling, or vice versa. The rails 110 and the rails 118 extend in substantially perpendicular directions (e.g., between 80 and 110 degrees, between 85 and 95 degrees, between 89 and 91 degrees). For example, in the cross-section illustrated in FIG. 1, the extension of the rails 110 along the major axis is shown and a thickness of the rails 118 along a minor axis is shown. The rails 118 can be spaced along the major axis of the rails 110. Thus, the cross-section illustrated in FIG. 1 includes ends of the rail 118-1 and the rail 118-2, which are laterally spaced from one another. The arrangement of the rails 110 and the rails 118 are further illustrated in FIG. 2.

One or more vias 120 (e.g., via 120-1 and via 120-2) extend from the rails 118 to contacts 122 (e.g., contact 122-1 and contact 122-2) at the stack of semiconductor dies 102. The vias 120 and contacts 122 are embedded within the semiconductor device assembly 100 such that they are not exposed at the cross-section illustrated in FIG. 1; components embedded in the semiconductor device assembly 100 are hidden in the present view and thus illustrated as dashed lines. The vias 120 can be implemented similarly to the vias 112. For example, the vias 120 can be spaced along a major axis of the rails 118 and extend through the gap fill 108. Given that the rails 118 are implemented at the layer of dielectric material 116, the vias 120 can extend through the layer of dielectric material 116 past the rails 110.

As illustrated, the via 120-1 couples with contact 122-1 exposed at the distal end of the semiconductor dies 106 opposite the semiconductor die 104. The contact 122-1 can connect to the semiconductor die 104 or any other of the semiconductor dies 106 directly (e.g., using a through via that does not connect to circuitry at metallization layers of dies through which it passes) or indirectly (e.g., by routing through circuitry at metallization layers of intermittent dies). Like the vias 112, in some embodiments, the vias 120 can extend from within the footprint of the semiconductor dies 106 or from beyond the footprint of the semiconductor dies 106. For example, as illustrated, the via 120-2 extends through the layer of dielectric material 116 and the gap fill 108 to the contact 122-2, which is disposed at an exposed portion of the semiconductor die 104 beyond the footprint of the semiconductor dies 106. In this way, the via 120-2 can extend through the gap fill 108 beyond the footprint of the semiconductor dies 106 to directly couple the rail 118-2 and the contact 122-2.

Given that the rails 110 can be at least partially covered by the layer of dielectric material 116, the rails 110 may not be exposed at the periphery of the semiconductor device assembly 100 (e.g., at a distal end of the semiconductor device assembly 100 opposite the semiconductor die 104). To provide external connectivity to the rails 110, a contact 124 (e.g., illustrated in greater detail in FIG. 2) coupled with the rails 110 can be exposed at the periphery of the semiconductor device assembly 100. The contact 124 can couple to the rails 110 through any connective circuitry. For example, one or more vias 126 can extend between and couple the contact 124 and the rails 110.

One or more contacts 128 (e.g., contact 128-1 and contact 128-2) can be disposed at the layer of dielectric material 116 and exposed at the periphery of the semiconductor device assembly 100. One or more vias 130 (e.g., via 130-1 and via 130-2) extend from the contacts 128 through the layer of dielectric material 116 and the gap fill 108 to contacts 132 (e.g., contact 132-1 and contact 132-2) at the stack of semiconductor dies 102. The contacts 128 can be positioned at the periphery of the semiconductor dies in locations spaced from the rails 118 such that the contacts 128 and the rails 118 are electrically isolated from one another by the layer of dielectric material 116. The contacts 128 can also be positioned such that vias 130 extending from the contacts 128 are spaced and electrically isolated from the rails 110. As illustrated in FIG. 1, the contacts 128 and the vias 130 are embedded within the semiconductor device assembly 100 to ensure that the vias 130 do not contact the rail 110 exposed in the cross-section illustrated in FIG. 1. In this way, the vias 130 can extend past the rails 110.

Like the rails 110 and the rails 118, the contacts 128 and the vias 130 can include conductive material to enable the contacts 128 and vias 130 to communicate signaling to the stack of semiconductor dies 102. In aspects, the contacts 128 and the vias 130 can be used to carry any kind of signaling. For example, the contacts 128 can be used to carry source voltage signals, ground signaling, I/O signaling, or any other signaling. The contacts 128 can carry different types of signaling from the rails 110 or the rails 118. As a specific example, the contacts 128 and the vias 130 communicate I/O signaling. The vias 130 can extend from individual contacts 128. In this way, each of the vias 130 and contacts 128 can be used to communicate different signaling.

The contacts 128 and the vias 130 can be implemented in unused areas between the rails 110 and the rails 118. Thus, the contacts 128 and the vias 130 can be implemented in different locations based on a particular implementation or routing scheme with which the contacts 128 and vias 130 are to comply. The contacts 128 and the vias 130 can be located within the footprint of the semiconductor dies 106 or beyond the footprint of the semiconductor dies 106. As illustrated, the via 130-1 extends from the contact 128-1 and couples with contact 132-1 exposed at the distal end of the semiconductor dies 106 opposite the semiconductor die 104. The contact 132-1 can connect to the semiconductor die 104 or any other of the semiconductor dies 106 directly (e.g., using a through via that does not connect to circuitry at metallization layers of dies through which it passes) or indirectly (e.g., by routing through circuitry at metallization layers of intermittent dies). The via 130-2 extends from the contact 128-2 through the layer of dielectric material 116 and the gap fill 108 to the contact 132-2, which is disposed at an exposed portion of the semiconductor die 104 beyond the footprint of the semiconductor dies 106. In this way, the via 130-2 can extend through the gap fill 108 beyond the footprint of the semiconductor dies 106 to directly couple the contact 128-2 and the contact 132-2.

In the illustrated embodiment a portion of the gap fill 108 protrudes along the layer of dielectric material 116 such that the layer of dielectric material 116 covers only a portion of the exposed surface opposite the semiconductor die 104. In this way, the contact 124 can be disposed at a protruded portion of the gap fill 108. In other embodiments the gap fill 108 can have a planar distal end opposite the semiconductor die 104. The layer of dielectric material 116 can be disposed over the distal end such that the gap fill 108 does not protrude past the layer of dielectric material 116. As a result, a distal end of the semiconductor device assembly 100 opposite the semiconductor die 104 can include the layer of dielectric material 116 and circuitry (e.g., rails 110, rails 118, and contacts 128) disposed thereat.

Although the stack of semiconductor dies 102 is illustrated as four semiconductor dies, other implementations are possible that include more or less semiconductor dies. For example, the stack of semiconductor dies 102 can be replaced with a stack of semiconductor dies having 2, 3, 5, 6, 8, 10, 12, 14, 16, or any other number of semiconductor dies. In some embodiments, the semiconductor die 104 could be replaced with multiple semiconductor dies disposed laterally adjacent one another. In aspects, the semiconductor dies 106 could be replaced with more or fewer semiconductor dies or multiple stacks of semiconductor dies coupled to different lateral locations on the semiconductor die 104. For example, multiple stacks of the semiconductor dies 106 can be coupled with the semiconductor die 104 in a rectangle pattern.

FIG. 2 illustrates a simplified schematic partial plan view of a semiconductor device assembly 100 in accordance with an embodiment of the present technology. The plan view can illustrate an exposed surface of the semiconductor device assembly 100 opposite the semiconductor die 104 (covered by the semiconductor dies 106, the gap fill 108, and the layer of dielectric material 116 and thus only the footprint is shown in FIG. 2). As illustrated, the footprint of the semiconductor die 104 corresponds to the footprint of the semiconductor device assembly 100. As discussed with respect to FIG. 1, semiconductor dies 106 can be coupled with the semiconductor die 104, and gap fill 108 can be disposed at the semiconductor die 104 around and over the semiconductor dies 106. Thus, the only footprint of the semiconductor dies 106 is illustrated in FIG. 2. At least a portion of the footprint of the semiconductor die 104 can extend beyond the footprint of the semiconductor dies 106.

As discussed with respect to FIG. 1, vias 112 (e.g., via 112-1, via 112-2, via 112-3, and via 112-4) are disposed through the gap fill 108 to the stack of semiconductor dies 102. Rails 110 (e.g., rail 110-1 and rail 110-2) are disposed over and coupled with the vias 112. For example, rail 110-1 couples with via 112-1 and via 112-2, and rail 110-2 couples with via 112-3 and via 112-4. Although illustrated as being within the footprint of the semiconductor dies 106, one or more of the vias 112 can extend from beyond the footprint of the semiconductor dies 106.

The layer of dielectric material 116 is at least partially disposed over the rails 110. Thus, the rails 110 are not exposed at the surface illustrated in FIG. 2. Instead, the dotted lines are used to show the footprint of the rails 110 in the illustrated plane in FIG. 2. The rails 110 extend along a major axis. The rails 110 have a width along a minor axis. The rails 110 can have a width sufficient to provide contact with the vias 112. Specifically, the rails 110 can have a width greater than or equal to the diameter of the vias 112. The vias 112 can be spaced along the rails 110. For example, the vias 112 are spaced along the major axis of the rails 110. The rails 110 can include a plurality of rails 110 spaced from one another. For example, the rails 110 can be spaced from one another along a minor axis of the rails 110.

Rails 118 (e.g., rail 118-1 and rail 118-2) can be exposed at the layer of dielectric material 116 spaced and electrically isolated from the rails 110. For example, the rails 118 are spaced above the rails 110 by at least a portion of the layer of dielectric material 116. Given that the rails 110 and the rails 118 are spaced from one another, the footprint of the rails 110 can overlap the footprint of the rails 118. As illustrated, the rails 118 are exposed at a periphery of the semiconductor device assembly 100; however, the rails 118 can be at least partially embedded within the layer of dielectric material 116. The rails 118 can extend along a major axis. The major axis of the rails 118 can be substantially perpendicular (e.g., between 80 and 100 degrees, between 85 and 95 degrees, between 89 and 91 degrees) to the major axis of the rails 110. In this way, the rails 118 and the rails 110 can extend in substantially perpendicular directions. A width of the rails can be defined by a minor axis of the rails 118. The rails 118 can include a plurality of rails. In aspects, the rails 118 can be spaced from one another along the minor axis of the rails 118. In some embodiments, the rails 118 are spaced from one another along the major axis of the rails 110, and the rails 110 are spaced along the major axis of the rails 118.

As discussed with respect to FIG. 1, vias 120 (e.g., via 120-1, via 120-2, via 120-3, and via 120-4) extend from the rails 118 through the gap fill 108 and the layer of dielectric material 116 to the stack of semiconductor dies 102. Multiple of the vias 120 can extend from each of the rails 118. For example, rail 118-1 couples with via 120-1 and via 120-3, and rail 118-2 couples with via 120-2 and via 120-4. The vias 120 can be spaced from one another along the major axis of the rails 118. For example, via 120-1 is spaced from via 120-3 along the major axis of the rails 118. The vias 120 can extend within the footprint of the semiconductor dies 106 or beyond the footprint of the semiconductor dies 106. For example, as illustrated, via 120-1 and via 120-3 extend from within the footprint of the semiconductor dies 106, and via 120-2 and via 120-4 extend from beyond the footprint of the semiconductor dies 106.

Given that the rails 110 are embedded at least partially beneath the layer of dielectric material 116, a contact 124 can be disposed at the periphery of the semiconductor device assembly 100 to provide external connectivity to the rails 110. For example, solder or other connective structures can be disposed at the contact 124 to connect the contact 124 to external components (e.g., a substrate or motherboard) that provide functionality (e.g., power, ground, I/O, or other signaling) to the semiconductor device assembly 100. The contact 124 can extend to the rails 110 through vias 126 (e.g., via 126-1 and via 126-2). An individual one of the vias 126 can extend from the contact 124 to each of the rails 110. For example, via 126-1 can extend to rail 110-1 and via 126-2 can extend to rail 110-2. Although illustrated as a single, unibody contact, the contact 124 can instead be implemented as a plurality of contacts coupled to each of the rails 110.

As discussed above, the rails 118 are exposed at the periphery of the semiconductor device assembly. As a result, external connectivity can be provided directly by the rails 118. For example, solder or other connective structures can be disposed directly on the rails 118 and used to connect the rails 118 to external components. Alternatively or additionally, a contact 202 coupled with the rails 118 can be disposed at the periphery of the semiconductor device assembly 100. Solder or other connective structures can be disposed at the contact 202 and used to connect the rails 118 to external components. Like the contact 124, in some cases, the contact 202 can be implemented as a plurality of contacts corresponding to the rails 118. As discussed above, in some embodiments, the rails 118 are at least partially covered by the layer of dielectric material 116. Thus, to remain coupled to the rails 118, vias (not shown) can be disposed between the contact 202 and the rails 118.

Contacts 128 (e.g., contact 128-1, contact 128-2, contact 128-3, and contact 128-4) can be disposed at the layer of dielectric material 116 and exposed at the periphery of the semiconductor device assembly 100. One or more vias 130 (e.g., via 130-1, via 130-2, via 130-3, and via-4) extend from the contacts 128 through the layer of dielectric material 116 and the gap fill 108 to contacts 132 (e.g., contact 132-1 and contact 132-2) at the stack of semiconductor dies 102. The contacts 128 and the vias 130 can be spaced from the rails 110 and the rails 118. For example, the contacts 128 and the vias 130 are spaced from the rails 110 and the rails 118 along axes that lie within a plane (e.g., the plane illustrated in FIG. 2) that has a normal vector defined by the major axis of the vias 130 (e.g., an axis extending into and out of the plane illustrated in FIG. 2) along which the vias 130 extend. The contacts 128 and the vias 130 can be implemented in different locations based on a particular implementation or routing scheme with which the contacts 128 and vias 130 are to comply. The contacts 128 and the vias 130 can be located within the footprint of the semiconductor dies 106 or beyond the footprint of the semiconductor dies 106. As illustrated, contact 128-1 and contact 128-3, having via 130-1 and via 130-3 extending therefrom, are located within the footprint of the semiconductor dies 106; contact 128-2 and contact 128-4, having via 130-2 and via 130-4 extending therefrom, are located beyond the footprint of the semiconductor dies 106. The contacts 128 and the vias 130 can provide external connectivity to the semiconductor device assembly 100. For example, solder or other connective structures can be disposed on the contacts 128 and used to connect the contacts 128 to external components.

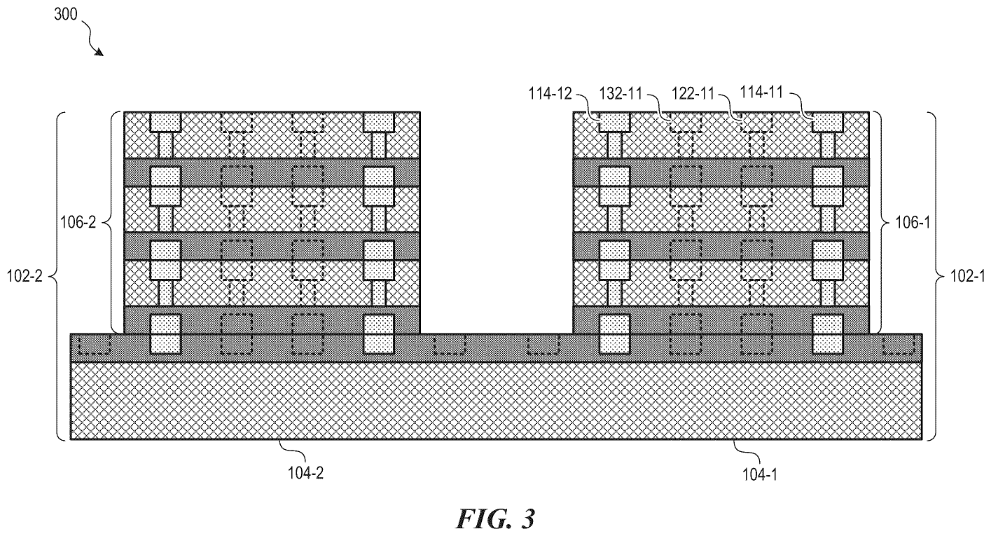

This disclosure now turns to a series of operations for fabricating semiconductor device assemblies in accordance with embodiments of the present technology. Specifically, FIGS. 3-8 illustrate simplified schematic cross-sectional views of a series of operations for fabricating semiconductor device assemblies in accordance with an embodiment of the present technology. The operations are illustrated with respect to a specific embodiment for ease of description. However, the operations described with respect to FIGS. 3-8 could be performed to fabricate semiconductor device assemblies in accordance with other embodiments.

FIG. 3 illustrates a simplified schematic cross-sectional view of a semiconductor device assembly at stage 300, where semiconductor dies 106 (e.g., semiconductor dies 106-1 and semiconductor dies 106-2) are coupled to a wafer of semiconductor dies, which includes a semiconductor die 104-1 and a semiconductor die 104-2. For example, the semiconductor dies 106-1 couple with the wafer of semiconductor dies at the semiconductor die 104-1 and the semiconductor dies 106-2 couple with the wafer of semiconductor dies at the semiconductor die 104-2. For the sake of brevity, various operations will be described with respect to the stack of semiconductor dies 102-1 (semiconductor die 104-1 and the semiconductor dies 106-1) and explicit description of the stack of semiconductor dies 102-2 (semiconductor die 104-2 and the semiconductor dies 106-2) and the various operations performed therewith are omitted. Unless otherwise noted, description of the stack of semiconductor dies 102-1, components related to the stack of semiconductor dies 102-1 (denoted by a suffix beginning with -1), or operations performed with respect to the stack of semiconductor dies 102-1 can apply similarly to the stack of semiconductor dies 102-2 and its related components (denoted by a suffix beginning with -2). Moreover, although only two stacks of semiconductor dies 102 are illustrated, any number of stacks of semiconductor dies can be implemented at different lateral locations.

As illustrated, the semiconductor die 104-1 and the semiconductor die 104-2 are implemented on a wafer of semiconductor dies. The wafer of semiconductor dies can include a plurality of individual semiconductor dies each implementing circuitry for a single semiconductor device assembly. Operations described herein are discussed as wafer-level operations for example only. In general, however, the operations disclosed herein can be performed at the die level for a single semiconductor device assembly or at the wafer or panel level for multiple semiconductor device assemblies. In aspects, the wafer of semiconductor dies can be of sufficient thickness to support the semiconductor device assembly during processing. Metallization layers of the semiconductor die 104-1 and the semiconductor die 104-2 can be formed by depositing layers of conductive material and layers of insulating material at a wafer on which the semiconductor die 104-1 and the semiconductor die 104-2 are implemented. For example, conductive material can be deposited to form contacts 122-12 and contacts 132-12 coupled to circuitry (e.g., transistors, diodes, traces, lines, vias, or other circuitry) at the metallization layer of the semiconductor die 104-1.

The stack of semiconductor dies 102-1 includes a semiconductor die 104-1 (e.g., a logic die) and one or more semiconductor dies 106-1 (e.g., memory dies). The semiconductor dies 106-1 can be coupled with the semiconductor die 104-1 in various portions or as a complete stack. For example, a stack of the semiconductor dies 106-1 can be cube-to-wafer bonded (e.g., hybrid bonded) to the semiconductor die 104-1. Alternatively, each of the semiconductor dies 106-1 can be stacked to the semiconductor die 104-1 one or multiple at a time. In some cases, the semiconductor dies 106-1 can be tested before being added to the assembly. In this way, yield can be improved by selecting “known good dies” or “know good cubes” for the semiconductor dies 106-1. Coupling the stack of semiconductor dies 106-1 with the semiconductor die 104-1 can form interconnects that couple circuitry at the semiconductor dies 106-1 and circuitry at the semiconductor die 104-1.

The semiconductor dies 106-1 are stacked to the semiconductor die 104-1 such that front sides of the semiconductor dies 106-1 face the front side of the semiconductor die 104-1. Once the stack of semiconductor dies 106-1 is attached to the semiconductor die 104-1, at least one contact (e.g., contact 122-12 and contact 132-12) can be beyond the footprint of the semiconductor dies 106-1 and left unconnected to the semiconductor dies 106-1. Contacts can be disposed at a distal end of the semiconductor dies 106-1 opposite the semiconductor die 104-1. As illustrated, contacts 114-1 (e.g., contact 114-11 and contact 114-12), contact 132-11, and contact 122-11 are exposed at the distal end of the semiconductor dies 106-1. As discussed above, semiconductor dies 106-2 can be similarly coupled with the semiconductor die 104-2.

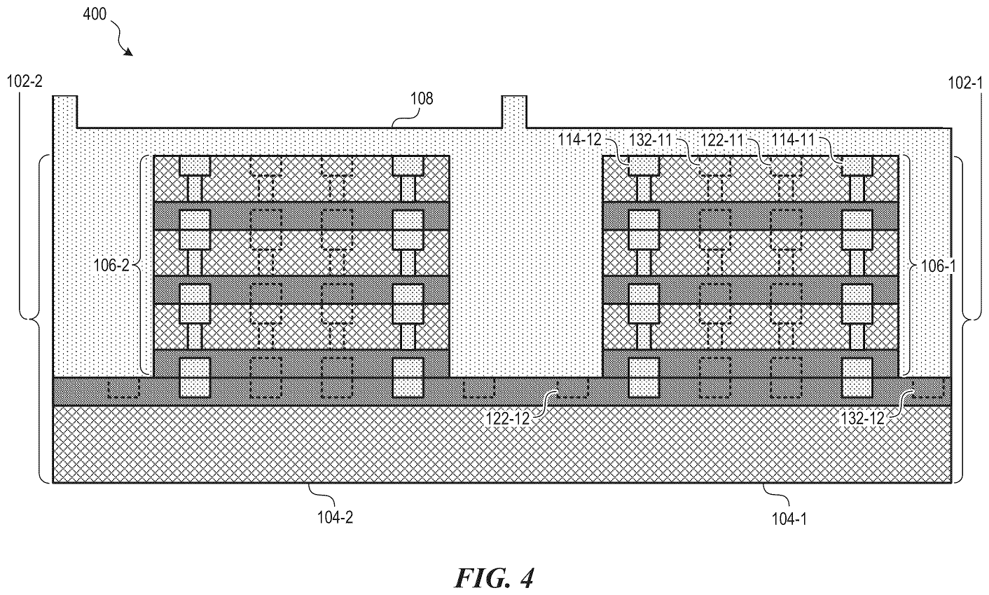

FIG. 4 illustrates a simplified schematic cross-sectional view of stage 400, where a gap fill 108 is disposed at the semiconductor die 104-1 and the semiconductor die 104-2 at least partially surrounding the semiconductor dies 106-1 and the semiconductor dies 106-2. In aspects, the gap fill 108 (e.g., dielectric fill, oxide fill, mold resin) can be disposed at portions of the semiconductor die 104-1 and the semiconductor die 104-2 exposed beyond the footprint of the semiconductor dies 106-1 and the semiconductor dies 106-2. The gap fill 108 can mechanically support and protect the semiconductor device assembly. In other aspects, the gap fill 108 can improve the thermal regulation of the semiconductor device assembly. In aspects, the gap fill 108 includes a dielectric material, such as silicon oxide, silicon nitride, silicon carbide, or silicon carbon nitride. The gap fill 108 be disposed through any appropriate technique, for example, dispensing, chemical vapor deposition (CVD), or physical vapor deposition (PVD). As illustrated, the gap fill 108 can be disposed over a distal end of the semiconductor dies 106-1 and the semiconductor dies 106-2 opposite the semiconductor die 104-1 and the semiconductor die 104-2. Once disposed, the gap fill 108 can cover the contacts 114, the contacts 122, or the contacts 132.

A distal end of the gap fill 108 opposite the semiconductor die 104-1 can have a recession at which a layer of dielectric material can be disposed. In this way, after the layer of dielectric material is disposed in the recession, the protrusion of gap fill can extend past the layer of dielectric material. The recession can be formed through any appropriate method. For example, the gap fill 108 can be selectively disposed to create the recession through deposition. Thus, removal of the gap fill 108 to create the recession may not be needed. In other cases, the gap fill 108 can be disposed with a planar distal end, and a portion of the gap fill 108 can be removed at the distal end to create the recession. The gap fill 108 can be removed through, for example, plasma etching, wet etching, CMP, or other suitable techniques.

At least a portion of the distal end of the gap fill 108 can be planarized to create a planar surface for disposing the layer of dielectric material and conductive material that implements circuitry. The planarization can be performed through, for example, CMP, back grinding, or other suitable techniques. Although illustrated with the recession in FIG. 4, in other embodiments, the distal end of the gap fill 108 can be a planar surface. In aspects, this may allow for a simpler planarization process where the omission of planarization from the protrusion is not needed. In these embodiments, the layer of dielectric material can be disposed where the protrusion of gap fill 108 is shown in FIG. 4. Thus, a distal end of the semiconductor device assembly opposite the semiconductor die 104-1 may not expose the gap fill 108.

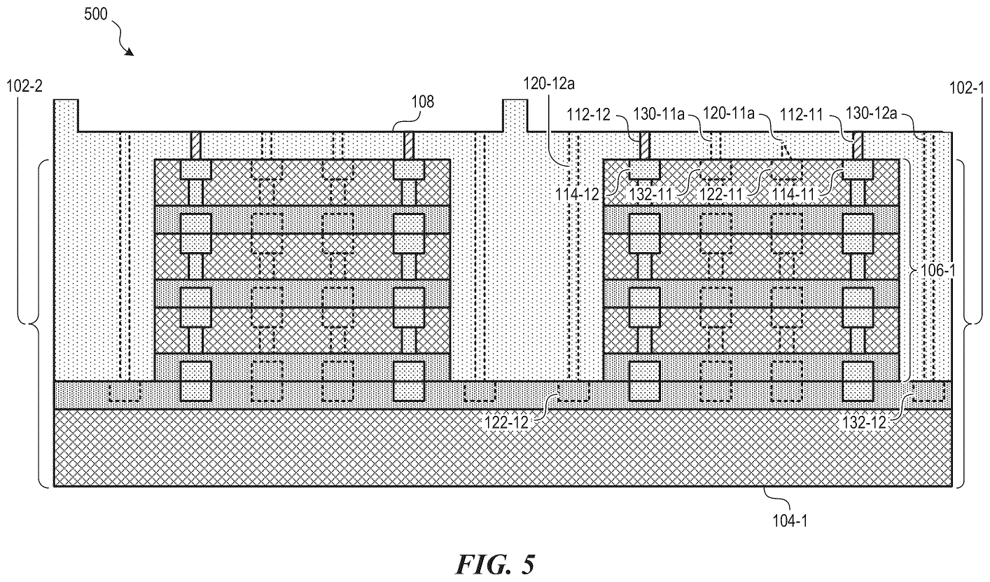

FIG. 5 illustrates a simplified schematic cross-sectional view of stage 500, where vias are disposed through the gap fill 108. As illustrated, vias 112-1 (e.g., via 112-11 and via 112-12) are disposed through the gap fill 108 and coupled with the contacts 114-1 (e.g., contact 114-11 and contact 114-12). First portions of vias 120-1a (e.g., a first portion of via 120-11a and a first portion of via 120-12a) and first portions of vias 130-1a (e.g., a first portion of via 130-11a and a first portion of via 130-12a) are disposed through the gap fill 108 and coupled with the contacts 122-1 (e.g., contact 122-11 and contact 122-12) and the contacts 132-1 (e.g., contact 132-11 and contact 132-12), respectively. Some of the vias can extend to a distal end of the semiconductor dies 106-1, and others of the vias can extend past the semiconductor dies 106-1 through the gap fill 108 to the semiconductor die 104-1. For example, the first portion of the via 120-11a extends to the contact 122-11 at the distal end of the semiconductor dies 106-1, and the first portion of the via 120-12a extends to the contact 122-12 at the semiconductor die 104-1. The vias can be exposed at the distal end of the gap fill 108.

The vias can be disposed through any appropriate technique. For example, openings can be created from the distal end of the gap fill 108 at lateral locations corresponding to the contact. The openings can extend entirely through the gap fill 108 to the contacts. In aspects, the openings can be created through drilling (e.g., laser drilling). Conductive material can be deposited in the openings to implement the vias. The vias can thus electrically couple with the stack of semiconductor dies 102-1. Any number of vias can be disposed through the gap fill 108. In aspects, the vias can be used to communicate power, ground, I/O, or other signals to/from the stack of semiconductor dies 102-1. Vias can similarly be disposed with respect to the stack of semiconductor dies 102-2.

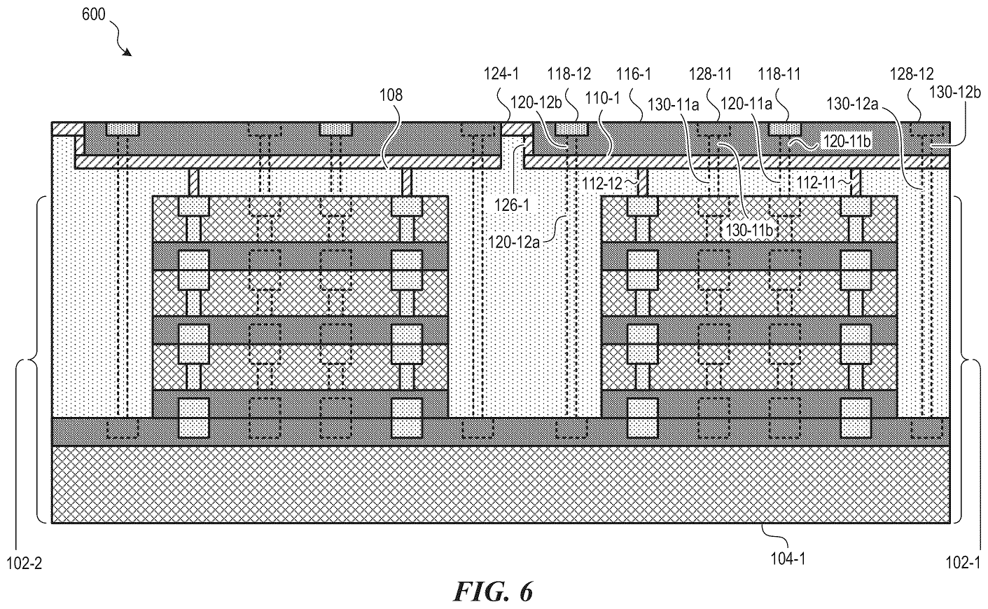

FIG. 6 illustrates a simplified schematic cross-sectional view of stage 600, where a layer of dielectric material 116-1 and various circuitry are disposed at the distal end of the gap fill 108. The layer of dielectric material 116 and conductive material to implement the circuitry can be disposed through, for example, CVD, PVD, plating, electroless plating, spin coating, and/or other suitable techniques. Rails 110-1 can be disposed at the distal end of the gap fill 108 and coupled with the vias 112-1 (e.g., via 112-11 and via 112-12). A layer of dielectric material 116-1 is disposed at the gap fill 108 at least partially over the rails 110-1. A contact 124-1 can be disposed at a periphery of the semiconductor device assembly (e.g., at a distal end opposite the semiconductor die 104-1). In some cases, the contact 124-1 can be disposed at a protruding portion of the gap fill 108. In other instances, the contact 124-1 can be implemented at the layer of dielectric material, for example, when the distal end of the semiconductor device opposite the semiconductor die 104-1 is implemented as a layer of dielectric material 116-1 absent the protruded portion of the gap fill 108. Vias 126-1 can be disposed between the contact 124-1 and the rails 110-1 to electrically couple these components. The vias 126-1 can extend at least partially through the layer of dielectric material 116-1.

Second portions of the vias 120-1b (e.g., second portion of the via 120-11b and second portion of the via 120-12b) and second portions of the vias 130-1b (e.g., second portion of the via 130-11b and second portion of the via 130-12b) are disposed through the layer of dielectric material 116-1 past the rails 110-2. The second portions of the vias 120-1b can attach to the first portions of the vias 120-1a (e.g., first portion of the via 120-11a and first portion of the via 120-12a) and first portions of the vias 130-1a (e.g., second portion of the via 130-11a and second portion of the via 130-12a). When combined, the first and second portions of the vias can implement unibody vias coupled with the stack of semiconductor dies 102-1. Although illustrated as disposed in two separate processes, in some embodiments, the first and second portions of the vias are disposed in a single process (e.g., after the layer of dielectric material is disposed).

Rails 118-1 (e.g., rail 118-11 and rail 118-12) can be disposed at the layer of dielectric material spaced from the rails 110-1. The rails 118-1 can couple with the second portions of the vias 120-1. For example, the rail 118-11 can be coupled with the via 120-11, and the rails 118-12 can couple with the via 120-12. The rails 118-1 can be exposed at a periphery of the semiconductor device assembly (e.g., at a distal end opposite the semiconductor die 104-1). In some embodiments, at least a portion of the rails 118-1 is embedded in the layer of dielectric material 116-1. Although not illustrated, a contact can be a layer of dielectric material coupled with the rails 118-1 to provide external connectivity to the rails 118-1.

Contacts 128-1 (e.g., contact 128-11 and contact 128-12) can similarly be disposed at the layer of dielectric material 116-1 and exposed at the periphery of the semiconductor device assembly. The contacts 128-1 can couple with the vias 130-1 (e.g., via 130-11 and via 130-12). For example, the contact 128-11 can couple with the second portion of the via 130-11b, and the contact 128-12 can couple with the second portion of the via 130-12b. The contacts 128-1 can provide external connectivity to the stack of semiconductor dies 102-1 through the vias 130-1.

Any of the circuitry can be created through any appropriate method. For example, the circuitry can be disposed by selectively disposing conductive material when disposing the layer of dielectric material 116-1. Alternatively or additionally, the circuitry can be implemented by creating an opening through at least a portion of the layer of dielectric material 116-1 and dispensing conductive material into the opening.

The contact 124-1, the contact coupled with the rails 118-1, and the contacts 128-1 can provide external connectivity (e.g., power, ground, I/O, or other signaling) to the semiconductor device assembly. These contacts can be arranged in a configuration that matches one or more external components (e.g., a motherboard) to which the semiconductor device assembly attaches. For example, these contacts can be arranged in a BGA configuration. Solder balls or other connective structures can be disposed at the contacts to provide connectivity to external components that provide various functionality (e.g., power, ground, I/O, or other signaling) to the semiconductor device assembly.

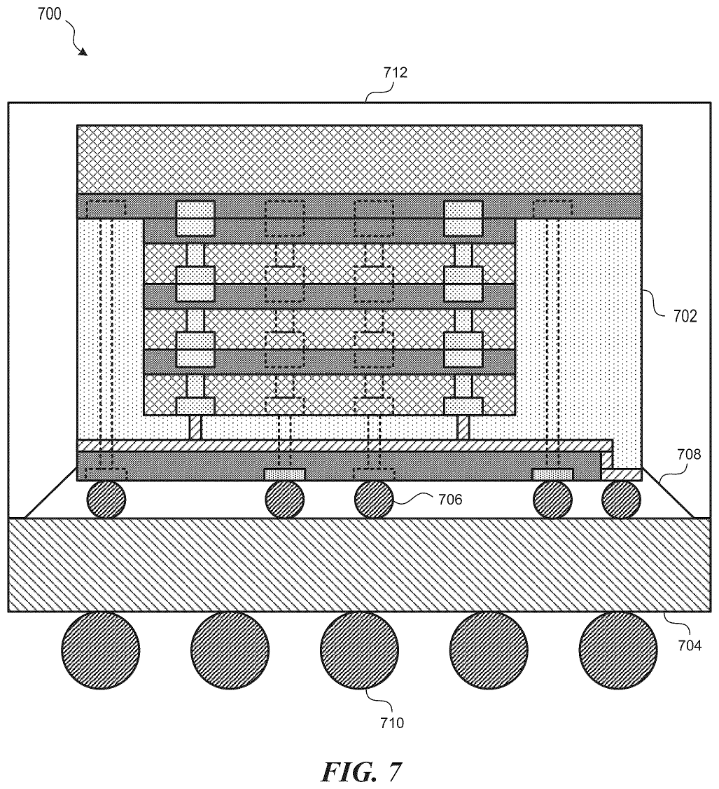

When the semiconductor device is assembled at the wafer level, the various stacks of semiconductor dies 102 can be singulated into individual semiconductor device assemblies. For example, the wafer that includes the semiconductor die 104-1, the gap fill 108, and the layer of dielectric material 116-1 can be sawed between the stacks of semiconductor dies 102 (e.g., the stack of semiconductor dies 102-1 and the stack of semiconductor dies 102-2). Once singulated, the individual semiconductor device assemblies can be coupled with a larger system. For example, the semiconductor device assembly can be flipped such that the layer of dielectric material 116-1 is at the bottom and the solder balls (or other connective structures) disposed at the contacts can couple with an external component (e.g., a motherboard). Given that the contacts can be arranged in a particular configuration to be compatible with the external component to which the semiconductor device assembly is attached, an additional substrate may not be needed to support the proper ball out of the assembly. In some cases, however, the contacts can be attached to an additional substrate (e.g., silicon interposer or printed circuit board (PCB)) that provides a specific arrangement of external contacts. An example semiconductor device assembly is illustrated in FIG. 7.

FIG. 7 illustrates a simplified schematic cross-sectional view of stage 700, where the semiconductor device assembly 702 is coupled to a substrate 704 and encapsulated. The semiconductor device assembly 702 can be a singulated one of the stacks of semiconductor dies illustrated in FIG. 6. The semiconductor device assembly 702 can be coupled to the substrate through connective structures 706 (e.g., solder). In some cases, the semiconductor device assembly 702 can be hybrid bonded to the substrate 704. Although illustrated as being flipped onto the substrate 704, in other embodiments, the semiconductor device assembly 702 can be wire-bonded to the substrate 704. In these embodiments, the semiconductor device assembly 702 need not be flipped onto the substrate 704. The substrate 704 can be a singulated substrate in accordance with one or more embodiments described herein. For example, the semiconductor device assembly 702 can be coupled with a panel-level or strip-level substrate that is sawed to singulate the substrate 704.

The substrate 704 can similarly include contacts at an upper surface. The connective structures 706 can implement interconnects that electrically couple the semiconductor device assembly 702 and the substrate 704. An underfill material 708 (e.g., capillary underfill) can be disposed between the semiconductor device assembly 702 and the substrate 704 at least partially surrounding the connective structures 706. The substrate 704 can include various circuitry (e.g., traces, lines, vias, or other connection structures) between the contacts at the upper surface and contacts at a lower side of the substrate 704 at which connective structures 710 (e.g., solder) are disposed. In this way, external connectivity (e.g., power, ground, I/O, or other signaling) can be provided through the connective structures 710. The semiconductor device assembly 702 and the substrate 704 can be at least partially encapsulated by an encapsulant material 712 (e.g., mold resin compound) to prevent electrical contact with or provide mechanical strength to the semiconductor device assembly.

Although in the foregoing example embodiment, semiconductor device assemblies have been illustrated and described as including a particular configuration of semiconductor dies, in other embodiments, assemblies can be provided with different configurations of semiconductor dies. For example, the semiconductor device assemblies illustrated in any of the foregoing examples could be implemented with, for example, multiple stacks of semiconductor dies or a single semiconductor die, mutatis mutandis.

In accordance with one aspect of the present disclosure, the semiconductor devices illustrated in the assemblies of FIGS. 1-7 could include memory dies, such as dynamic random access memory (DRAM) dies, NOT-AND (NAND) memory dies, NOT-OR (NOR) memory dies, magnetic random access memory (MRAM) dies, phase change memory (PCM) dies, ferroelectric random access memory (FeRAM) dies, static random access memory (SRAM) dies, or the like. In an embodiment in which multiple dies are provided in a single assembly, the semiconductor devices could include memory dies of a same kind (e.g., both NAND, both DRAM, etc.) or memory dies of different kinds (e.g., one DRAM and one NAND, etc.). In accordance with another aspect of the present disclosure, the semiconductor dies of the assemblies illustrated and described above could be logic dies (e.g., controller dies, processor dies, etc.) or a mix of logic and memory dies (e.g., a memory controller die and a memory die controlled thereby).

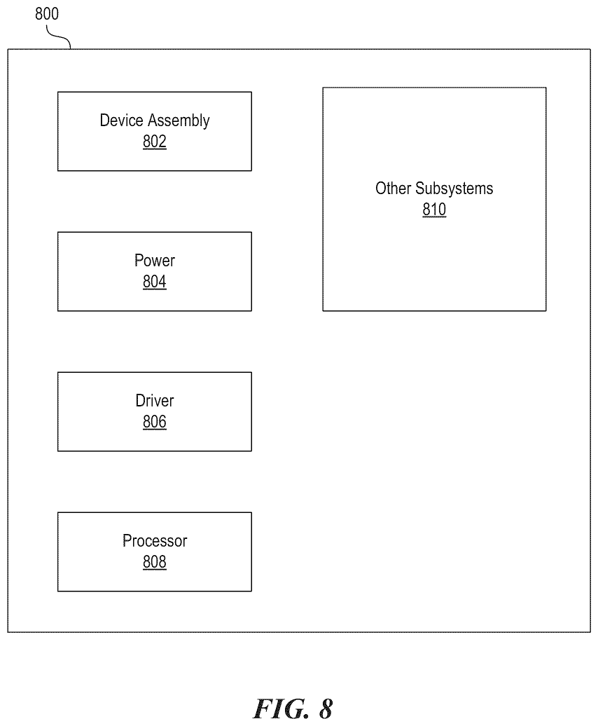

Any one of the semiconductor devices and semiconductor device assemblies described above with reference to FIGS. 1-7 can be incorporated into any of a myriad of larger and/or more complex systems, a representative example of which is system 800 shown schematically in FIG. 8. The system 800 can include a semiconductor device assembly 802 (e.g., a discrete semiconductor device), a power source 804, a driver 806, a processor 808, and/or other subsystems or components 810. The semiconductor device assembly 802 can include features generally similar to those of the semiconductor device assemblies described above with reference to FIGS. 1-7. The resulting system 800 can perform any of a wide variety of functions, such as memory storage, data processing, and/or other suitable functions. Accordingly, representative systems 800 can include, without limitation, handheld devices (e.g., mobile phones, tablets, digital readers, and digital audio players), computers, vehicles, appliances, and other products. Components of the system 800 may be housed in a single unit or distributed over multiple, interconnected units (e.g., through a communications network). The components of the system 800 can also include remote devices and any of a wide variety of computer readable media.

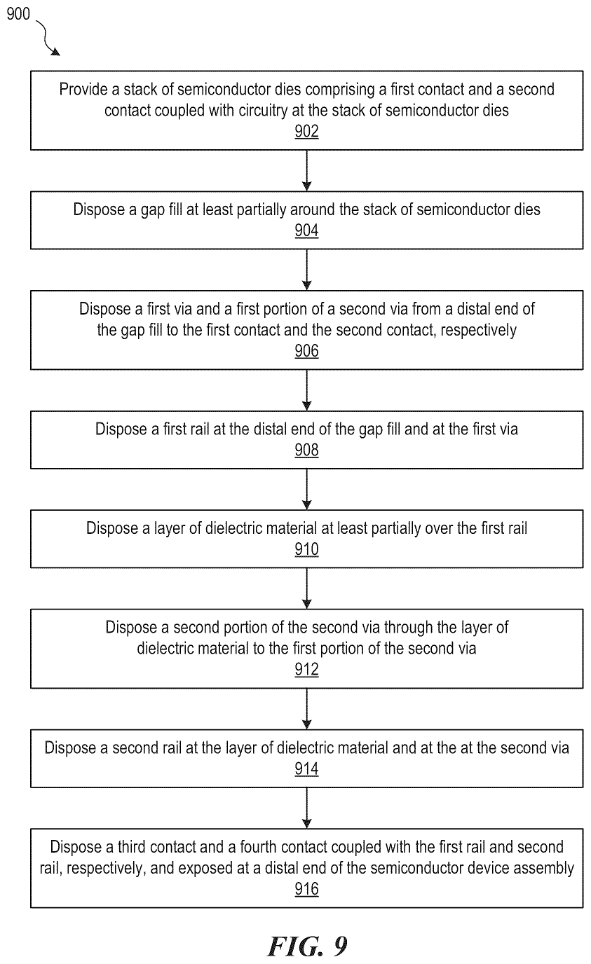

FIG. 9 illustrates an example method 900 for fabricating a semiconductor device assembly in accordance with an embodiment of the present technology. Although illustrated in a particular configuration, one or more operations of the method 900 may be omitted, repeated, or reorganized. Additionally, the method 900 may include other operations not illustrated in FIG. 9, for example, operations detailed in one or more other methods described herein.

At 902, a stack of semiconductor dies is provided. The stack of semiconductor dies includes a first semiconductor die, one or more second semiconductor dies, at least one first contact coupled with circuitry at the stack of semiconductor dies, and at least one second contact coupled with the circuitry (e.g., traces, lines, vias, transistors, diodes, or other circuitry) at the stack of semiconductor dies. The first and second contact can be disposed at the first semiconductor die or at a distal end of the one or more second semiconductor dies opposite the first semiconductor die. In some cases, the first semiconductor die is a logic die, such as a memory controller or an interface die, and the second semiconductor dies are memory dies.

At 904, a gap fill is disposed at least partially around the stack of semiconductor dies and over a distal end of the one or more second semiconductor dies opposite the first semiconductor die. In some cases, the gap fill is a dielectric fill, an oxide fill, or a mold resin. The gap fill can be disposed at an exposed portion of the first semiconductor die exposed beyond the footprint of the first semiconductor die.

At 906, at least one first via and a second portion of at least one second via are disposed through the gap fill. The first via can extend from a distal end of the gap fill to the first contact. The first portion of the second via can extend from the distal end of the gap fill to the second contact. The via can be disposed by creating a hole in the gap fill and dispensing conductive material in the opening.

At 908, one or more first rails are disposed at the distal end of the gap fill and at the at least one first via. In this way, the one or more first rails can be coupled with the at least one first via.

At 910, a layer of dielectric material is disposed at least partially over the first rails. The layer of dielectric material can include, for example, silicon oxide, silicon nitride, silicon carbide, silicon carbon nitride, or any other dielectric material.

At 912, a second portion of the at least one second via is disposed through the layer of dielectric material to the first portion of the at least one second via. The second portion of the at least one second via can be formed through selective deposition of conductive material during a same process as disposing the layer of dielectric material. In other cases, an opening can be drilled through the layer of dielectric material after it has been disposed, and conductive material can be dispensed into the opening.

At 914, one or more second rails are disposed at the layer of dielectric material and at the at least one second via. In this way, the one or more second rails can be coupled with the at least one second via. The second rails can be spaced vertically (e.g., along a major axis of the second via) from the first rails. A footprint of the second rails can partially overlap a footprint of the first rails.

At 916, one or more third contacts coupled with the one or more first rails and one or more fourth contacts coupled with the one or more second rails are disposed. The third contacts and the fourth contacts can be exposed at the distal end of the semiconductor device assembly opposite the first semiconductor die. The third contacts can couple with the first rails through, for example, vias extending through the layer of dielectric material. In some cases, the fourth contacts can be implemented in combination with the second rails. For example, the fourth contacts can be implemented as an exposed surface of the rails such that electrical contact can be made directly with the second rails. The third and fourth contacts can provide external connectivity to external components that provide functionality (e.g., power, ground, I/O, or other signaling) to the semiconductor device assembly. Thus, various signaling can be provided to the semiconductor device assembly through the first and second rails and vias.

Specific details of several embodiments of semiconductor devices, and associated systems and methods, are described above. Depending upon the context in which it is used, the term “substrate” can refer to a wafer-level substrate or to a singulated, die-level substrate. Furthermore, unless the context indicates otherwise, structures disclosed herein can be formed using conventional semiconductor-manufacturing techniques. Materials can be deposited, for example, using chemical vapor deposition, physical vapor deposition, plating, electroless plating, spin coating, and/or other suitable techniques. Similarly, materials can be removed, for example, using plasma etching, wet etching, CMP, or other suitable techniques.

The technology disclosed herein relates to semiconductor devices, systems with semiconductor devices, and related methods for manufacturing semiconductor devices. The term “semiconductor device” generally refers to a solid-state device that includes one or more semiconductor materials. Examples of semiconductor devices include logic devices, memory devices, and diodes, among others. Furthermore, the term “semiconductor device” can refer to a finished device or to an assembly or other structure at various stages of processing before becoming a finished device. Depending upon the context in which it is used, the term “substrate” can refer to a structure that supports electronic components (e.g., a die), such as a PCB or wafer-level substrate, a die-level substrate, or another die for die-stacking or 3DI applications.

The devices discussed herein, including a memory device, may be formed on a semiconductor substrate or die, such as silicon, germanium, silicon-germanium alloy, gallium arsenide, gallium nitride, etc. In some cases, the substrate is a semiconductor wafer. In other cases, the substrate may be a silicon-on-insulator (SOI) substrate, such as silicon-on-glass (SOG) or silicon-on-sapphire (SOP), or epitaxial layers of semiconductor materials on another substrate. The conductivity of the substrate, or sub-regions of the substrate, may be controlled through doping using various chemical species including, but not limited to, phosphorous, boron, or arsenic. Doping may be performed during the initial formation or growth of the substrate, by ion implantation, or by any other doping means.

The functions described herein may be implemented in hardware, software executed by a processor, firmware, or any combination thereof. Other examples and implementations are within the scope of the disclosure and appended claims. Features implementing functions may also be physically located at various positions, including being distributed such that portions of functions are implemented at different physical locations.

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, the terms “vertical,” “lateral,” “upper,” “lower,” “above,” and “below” can refer to relative directions or positions of features in the semiconductor devices in view of the orientation shown in the Figures. For example, “upper” or “uppermost” can refer to a feature positioned closer to the top of a page than another feature. These terms, however, should be construed broadly to include semiconductor devices having other orientations, such as inverted or inclined orientations where top/bottom, over/under, above/below, up/down, and left/right can be interchanged depending on the orientation.

From the foregoing, it will be appreciated that specific embodiments of the invention have been described herein for purposes of illustration but that various modifications may be made without deviating from the scope of the invention. Rather, in the foregoing description, numerous specific details are discussed to provide a thorough and enabling description for embodiments of the present technology. One skilled in the relevant art, however, will recognize that the disclosure can be practiced without one or more of the specific details. In other instances, well-known structures or operations often associated with memory systems and devices are not shown, or are not described in detail, to avoid obscuring other aspects of the technology. In general, it should be understood that various other devices, systems, and methods in addition to those specific embodiments disclosed herein, may be within the scope of the present technology.

What is claimed is:

1. A semiconductor device assembly, comprising:
a stack of semiconductor dies including a first semiconductor die, one or more second semiconductor dies, at least one first contact coupled with circuitry at the stack of semiconductor dies, and at least one second contact coupled with the circuitry at the stack of semiconductor dies;
a gap fill at least partially surrounding the stack of semiconductor dies and disposed over a distal end of the one or more second semiconductor dies opposite the first semiconductor die;
one or more first rails disposed at a distal end of the gap fill opposite the first semiconductor die;
at least one first via extending from the one or more first rails to the at least one first contact;
a layer of dielectric material disposed at least partially over the one or more first rails;
one or more second rails disposed at the layer of dielectric material;
at least one second via extending from the one or more second rails past the one or more first rails to the at least one second contact;
one or more third contacts coupled with the one or more first rails and exposed at a distal end of the semiconductor device assembly opposite the first semiconductor die; and
one or more fourth contacts coupled with the one or more second rails and exposed at the distal end of the semiconductor device assembly,
wherein the one or more first rails comprise a first of source voltage rails or ground reference rails and the one or more second rails comprise another of the source voltage rails or the ground reference rails.

2. The semiconductor device assembly of claim 1, wherein:
the one or more first rails extend along a first major axis; and
the one or more second rails extend along a second major axis substantially perpendicular to the first major axis.

3. The semiconductor device assembly of claim 2, wherein:
the one or more first rails comprise a plurality of first rails spaced along the second major axis; or
the one or more second rails comprise a plurality of second rails spaced along the first major axis.

4. The semiconductor device assembly of claim 1, wherein:
the at least one first via comprises a plurality of first vias; and
the plurality of first vias are spaced along a major axis of the one or more first rails.

5. The semiconductor device assembly of claim 1, wherein:
the at least one second via comprises a plurality of second vias; and
the plurality of second vias are spaced along a major axis of the one or more second rails.

6. The semiconductor device assembly of claim 1, wherein the stack of semiconductor dies further comprises a fifth contact coupled with the circuitry at the stack of semiconductor dies, the semiconductor device assembly further comprising:
a sixth contact disposed at the layer of dielectric material and exposed at the distal end of the semiconductor device assembly; and
a third via extending from the sixth contact to the fifth contact, the third via spaced from the one or more first rails and the one or more second rails along one or more axes within a plane, wherein a major axis along which the third via extends is normal to the plane.

7. The semiconductor device assembly of claim 1, wherein:
the first semiconductor die has a first footprint;
the one or more second semiconductor dies have a second footprint;
the at least one first contact or the at least one second contact is disposed at the first semiconductor die and at least partially exposed beyond the second footprint; and
the at least one first via or the at least one second via extends through the gap fill beyond the second footprint.

8. The semiconductor device assembly of claim 1, wherein:
the first semiconductor die comprises a logic die; and
the one or more second semiconductor dies comprise memory dies.

9. A method for fabricating a semiconductor device assembly, comprising:
providing a stack of semiconductor dies comprising a first semiconductor die, one or more second semiconductor dies, at least one first contact coupled with circuitry at the stack of semiconductor dies, and at least one second contact coupled with the circuitry at the stack of semiconductor dies;
disposing a gap fill at least partially around the stack of semiconductor dies and over a distal end of the one or more second semiconductor dies opposite the first semiconductor die;
disposing at least one first via from a distal end of the gap fill opposite the first semiconductor die through the gap fill to the at least one first contact;
disposing a first portion of at least one second via from the distal end of the gap fill through the gap fill to the at least one second contact;
disposing one or more first rails at the distal end of the gap fill and at the at least one first via;
disposing a layer of dielectric material at least partially over the one or more first rails;
disposing a second portion of the at least one second via through the layer of dielectric material to the first portion of the at least one second via;
disposing one or more second rails at the layer of dielectric material and at the at least one second via;
disposing one or more third contacts coupled with the one or more first rails and exposed at a distal end of the semiconductor device assembly opposite the first semiconductor die; and
disposing one or more fourth contacts coupled with the one or more second rails and exposed at the distal end of the semiconductor device assembly opposite the first semiconductor die,
wherein the one or more first rails comprise a first of source voltage rails or ground reference rails and the one or more second rails comprise another of the source voltage rails or the ground reference rails.

10. The method of claim 9, further comprising:
a wafer of semiconductor dies comprising the first semiconductor die and an additional first semiconductor die;
coupling one or more additional second semiconductor dies to the additional first semiconductor die;
disposing the gap fill at least partially around the one or more additional second semiconductor dies;
disposing at least one additional first via from the distal end of the gap fill to the additional first semiconductor die or the one or more additional second semiconductor dies;
disposing a first portion of at least one additional second via from the distal end of the gap fill to the additional first semiconductor die or the one or more additional second semiconductor dies;
disposing one or more additional first rails at the distal end of the gap fill and at the at least one additional first via;
disposing the layer of dielectric material at least partially over the one or more additional first rails;
disposing a second portion of the at least one additional second via through the layer of dielectric material to the first portion of the at least one additional second via;
disposing one or more additional second rails at the layer of dielectric material and at the second portion of at least one additional second via;
disposing one or more additional third contacts coupled with the one or more additional first rails and exposed at the distal end of the semiconductor device assembly;
disposing one or more additional fourth contacts coupled with the one or more additional second rails and exposed at the distal end of the semiconductor device assembly; and
sawing the wafer of semiconductor dies to singulate the first semiconductor die and the additional first semiconductor die.

11. The method of claim 9, further comprising:
creating at least one first opening and at least one second opening extending through the gap fill to the at least one first contact and the at least one second contact, respectively;
disposing conductive material within the at least one first opening to implement the at least one first via extending through the gap fill to the at least one first contact; and
disposing conductive material within the at least one second opening to implement the first portion of the at least one second via extending through the gap fill to the at least one second contact.

12. The method of claim 9, further comprising:
removing at least a portion of the gap fill at the distal end of the gap fill to create recession; and
disposing the one or more first rails, the one or more second rails, and the layer of dielectric material at the recession.

13. The method of claim 9, wherein the stack of semiconductor dies further comprises a fifth contact coupled with the circuitry at the stack of semiconductor dies, the method further comprising:
disposing a sixth contact at the layer of dielectric material and exposed at the distal end of the semiconductor device assembly; and
disposing a third via extending from the sixth contact to the fifth contact, the third via spaced from the one or more first rails and the one or more second rails along one or more axes within a plane, wherein a major axis along which the third via extends is normal to the plane.

14. The method of claim 9, wherein:
the one or more first rails extend along a first major axis; and
the one or more second rails extend along a second major axis substantially perpendicular to the first major axis.

15. The method of claim 9, wherein:
the first semiconductor die has a first footprint;
the one or more second semiconductor dies have a second footprint;
the at least one first contact or the at least one second contact is disposed at the first semiconductor die and at least partially exposed beyond the second footprint; and
the at least one first via or the first portion of the at least one second via extends through the gap fill beyond the second footprint.

16. A semiconductor device assembly, comprising:
a stack of semiconductor dies comprising a first semiconductor die, one or more second semiconductor dies, at least one first contact coupled with circuitry at the stack of semiconductor dies, and at least one second contact coupled with the circuitry at the stack of semiconductor dies;
a gap fill at least partially surrounding the stack of semiconductor dies and disposed over a distal end of the one or more second semiconductor dies opposite the first semiconductor die;
one or more first rails having a first footprint;
at least one first via extending from the one or more first rails to the at least one first contact;
a layer of dielectric material disposed at least partially over the one or more first rails;
one or more second rails disposed at the layer of dielectric material, the one or more second rails electrically isolated from the one or more first rails and having a second footprint, wherein the second footprint partially overlaps the first footprint;
at least one second via extending from the one or more second rails past the one or more first rails to the at least one second contact;
one or more third contacts coupled with the one or more first rails and exposed at a distal end of the semiconductor device assembly opposite the first semiconductor die; and
one or more fourth contacts coupled with the one or more second rails and exposed at the distal end of the semiconductor device assembly,
wherein the one or more first rails comprise a first of source voltage rails or ground reference rails and the one or more second rails comprise another of the source voltage rails or the ground reference rails.

17. The semiconductor device assembly of claim 16, wherein:
the one or more first rails extend along a first major axis; and
the one or more second rails extend along a second major axis substantially perpendicular to the first major axis.

18. The semiconductor device assembly of claim 17, wherein:
the one or more first rails comprise a plurality of first rails spaced along the second major axis; or
the one or more second rails comprise a plurality of second rails spaced along the first major axis.

19. The semiconductor device assembly of claim 16, wherein the stack of semiconductor dies further comprises a fifth contact coupled with the circuitry at the stack of semiconductor dies, the semiconductor device assembly further comprising:
a sixth contact disposed at the layer of dielectric material and exposed at the distal end of the semiconductor device; and
a third via extending from the sixth contact to the fifth contact, the third via spaced from the one or more first rails and the one or more second rails along one or more axes within a plane, wherein a major axis along which the third via extends is normal to the plane.

20. The semiconductor device assembly of claim 16, wherein:
the first semiconductor die comprises a logic die; and
the one or more second semiconductor dies comprise memory dies.
